(19) United States
(12) Patent Application Publication
(10) Pub. No.: US 2012/0228751 A1
(43) Pub. Date: Sep. 13, 2012

(54) SEMICONDUCTOR PACKAGE AND METHOD OF MANUFACTURING THE SAME

(75) Inventor: In-Sang SONG, Seoul (KR)

(73) Assignee: SAMSUNG ELECTRONICS CO., LTD., Suwon-si (KR)

(21) Appl. No.: 13/414,034

(22) Filed: Mar. 7, 2012

(30) Foreign Application Priority Data
Mar. 7, 2011 (KR) 10-2011-0019753
Jul. 13, 2011 (KR) 10-2011-0069193

(51) Int. Cl. H01L 23/552; H01L 21/50; H01L 23/48

(52) U.S. Cl. 257/660; 257/774; 438/109; 257/E23.011; 257/E21.499; 257/E23.114

(57) ABSTRACT

A semiconductor package and method of manufacture are provided. The semiconductor package may include a package substrate, a semiconductor chip, a molding member and a grounding member. The package substrate may include a ground pad and a signal pad. The semiconductor chip may be arranged on an upper surface of the package substrate. The semiconductor chip may be electrically connected with the signal pad of the package substrate. The molding member may be formed on the upper surface of the package substrate to cover the semiconductor chip. The grounding member may be arranged on a surface of the molding member. The grounding member may be electrically connected with the ground pad.

### CROSS-RELATED APPLICATION

This application claims priority from Korean Patent Application No. 2011-19753, filed on Mar. 7, 2011, and Korean Patent Application No. 2011-69193, filed on Jul. 13, 2011, in the Korean Intellectual Property Office, the contents of which are herein incorporated by reference in their entirety.

### BACKGROUND

1. Field

Articles of manufacture, packages, and methods consistent with the present disclosure relate to a semiconductor package and a method of manufacturing the same.

2. Description of the Related Art

Several semiconductor fabrication processes may be performed on a semiconductor substrate to mount semiconductor chips. In order to mount the semiconductor chips on a printed circuit board (PCB), a packaging process may be performed on the semiconductor chips to form semiconductor packages.

As a size of a portable electronic device becomes smaller and a transmission speed of data becomes faster, electromagnetic interference (EMI) may deteriorate a capacity of the semiconductor package.

In order to shield the semiconductor package from the EMI, a ground to the semiconductor package may be provided. In one example, a metal cover for shielding the EMI may be placed over the semiconductor package on the PCB and electrically connected with a ground pad of a printed circuit board (PCB) on which the semiconductor package is mounted. The metal cover is configured to surround the semiconductor package, and it is required to provide space between the metal cover and the semiconductor package. Thus, the metal cover may increase a thickness of the semiconductor package.

### SUMMARY

Exemplary embodiments provide a semiconductor package capable of shielding an EMI with a thin thickness.

Exemplary embodiments also provide a method of manufacturing the above-mentioned semiconductor package.

According to an aspect of an exemplary embodiment, there is provided a semiconductor package. The semiconductor package may include a package substrate, a semiconductor chip, a molding member and a grounding member. The package substrate may include a ground pad and a signal pad. The semiconductor chip may be arranged on an upper surface of the package substrate. The semiconductor chip may be electrically connected with the signal pad of the package substrate. The molding member may be formed on the upper surface of the package substrate to cover the semiconductor chip. The grounding member may be arranged on a surface of the molding member. The grounding member may be electrically connected with the ground pad.

In some exemplary embodiments, the grounding member may include a ground layer formed on the surface of the molding member, and a ground contact extending over a portion of a lower surface of the package substrate from the ground layer. The grounding contact may electrically make contact with the ground contact.

The semiconductor chip may include a ground pattern electrically connected to the ground pad. The molding member may have an opening configured to expose the ground pattern of the semiconductor chip. The grounding member may include a ground layer formed on the surface of the molding member, and a ground contact formed in the opening. The ground contact may electrically make contact with the ground layer and the ground pattern of the semiconductor chip.

The semiconductor package may further include an interposer chip stacked on an upper surface of the semiconductor chip. The interposer chip may include a ground pattern electrically connected between the ground pad and the grounding member.

The molding member may have an opening configured to expose the ground pattern of the interposer chip. The grounding member may include a ground layer formed on the surface of the molding member, and a ground contact formed in the opening. The ground contact may electrically make contact with the ground layer and the ground pattern of the interposer chip.

The semiconductor package may further include a second semiconductor chip stacked on the upper surface of the semiconductor chip. The second semiconductor chip may be covered with the molding member.

The semiconductor package may further include a plug formed through the semiconductor chip. The plug may be electrically connected between the second semiconductor chip and the signal pad of the semiconductor chip.

The grounding member may include an adhesive layer formed on the surface of the molding member, and a ground may be attached to the molding member via the adhesive layer. The ground may electrically make contact with the ground pad.

According to another aspect of an exemplary embodiment, there is provided a method of manufacturing a semiconductor package. In the method of manufacturing the semiconductor package, a semiconductor chip may be arranged on an upper surface of a package substrate having a ground pad and a signal pad. The semiconductor chip may be electrically connected with the signal pad of the package substrate. The molding member may be formed on the upper surface of the package substrate to cover the semiconductor chip. The grounding member may be formed on a surface of the molding member. The grounding member may be electrically connected with the ground pad.

The forming the grounding member may include forming a ground layer on the surface of the molding member, and extending a ground contact over a portion of a lower surface of the package substrate from the ground layer. The grounding contact may electrically make contact with the ground contact.

The method may further include forming a ground pattern on the semiconductor chip. The ground pattern may be electrically connected to the ground pad. Forming the grounding member may include forming a ground layer on the surface of the molding member, and extending a ground contact from the ground layer. The ground contact may electrically make contact with the ground pattern of the semiconductor chip.

The forming the molding member may further include forming an opening in the molding member. The opening may be configured to expose the ground pattern of the semiconductor chip. The ground contact may be formed in the opening.

The method may further include stacking an interposer chip on an upper surface of the semiconductor chip. The interposer chip may include a ground pattern electrically connected between the ground pad and the grounding member.

The forming the grounding member may include forming a ground layer on the surface of the molding member, and extending a ground contact from the ground layer. The ground contact may electrically make contact with the ground pattern of the interposer chip.

The forming the molding member may further include forming an opening in the molding member. The opening may be configured to expose the ground pattern of the interposer chip. The ground contact may be formed in the opening.

### BRIEF DESCRIPTION OF THE DRAWINGS

Exemplary embodiments will be more clearly understood from the following detailed description taken in conjunction with the accompanying drawings, in which:

FIG. 1 is a cross-sectional view illustrating a semiconductor package in accordance with an exemplary embodiment;

FIGS. 2 to 5 are cross-sectional views illustrating a method of manufacturing the semiconductor package in FIG. 1;

FIG. 6 is a cross-sectional view illustrating a semiconductor package in accordance with another exemplary embodiment;

FIG. 7 is a plan view illustrating a semiconductor chip of the semiconductor package in FIG. 6;

FIGS. 8 to 12 are cross-sectional views illustrating a method of manufacturing the semiconductor package in FIG. 6;

FIG. 13 is a cross-sectional view illustrating a semiconductor package in accordance with another exemplary embodiment;

FIG. 14 is a plan view illustrating an interposer chip of the semiconductor package in FIG. 13;

FIGS. 15 to 20 are cross-sectional views illustrating a method of manufacturing the semiconductor package in FIG. 13;

FIG. 21 is a cross-sectional view illustrating a semiconductor package in accordance with another exemplary embodiment;

FIGS. 22 and 23 are cross-sectional views illustrating a method of manufacturing the semiconductor package in FIG. 21;

FIG. 24 is a cross-sectional view illustrating a semiconductor package in accordance with another exemplary embodiment; and

FIG. 25 is a cross-sectional view illustrating a semiconductor package in accordance with another exemplary embodiment.

### DETAILED DESCRIPTION

Various exemplary embodiments will be described more fully hereinafter with reference to the accompanying drawings, in which some exemplary embodiments are shown. The present inventive concept may, however, be embodied in many different forms and should not be construed as limited to the exemplary embodiments set forth herein. Rather, these exemplary embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments will be explained in detail with reference to the accompanying drawings.

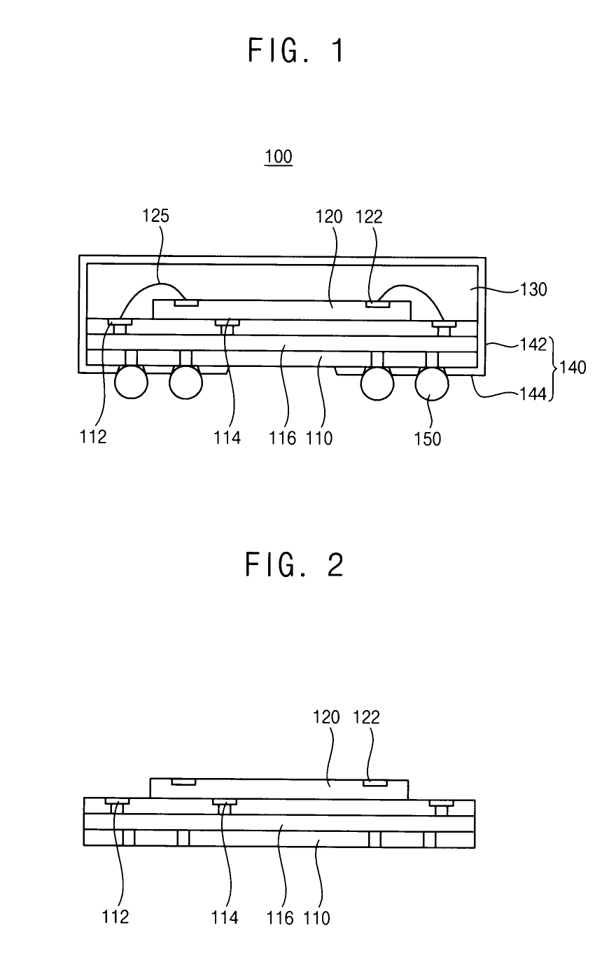

FIG. 1 is a cross-sectional view illustrating a semiconductor package in accordance with an exemplary embodiment.

Referring to FIG. 1, a semiconductor package 100 of this exemplary embodiment may include a package substrate 110, a semiconductor chip 120, conductive wires 125, a molding member 130, a grounding member 140 and external terminals 150.

The package substrate 110 may include signal pads 112, ground pads 114 and a circuit pattern 116. In some exemplary embodiments, the signal pads 112 and the ground pads 114 may be arranged on an upper surface of the package substrate 110. The signal pads 112 may be electrically connected with the circuit pattern 116. The circuit pattern 116 may have a lower end exposed through a lower surface of the package substrate 110.

The semiconductor chip 120 may be arranged on the upper surface of the package substrate 110. The semiconductor chip 120 may be attached to the upper surface of the package substrate 110 using an adhesive. The semiconductor chip 120 may have bonding pads 122. In some exemplary embodiments, the bonding pads 122 may be arranged on an upper surface of the semiconductor chip 120.

The conductive wires 125 may be electrically connected between the bonding pads 122 of the semiconductor chip 120 and the signal pads 112 of the package substrate 110. In some exemplary embodiments, the conductive wires 125 may include a metal wire such as an aluminum wire, a gold wire, etc. Alternatively, when the bonding pads 122 are arranged on a lower surface of the semiconductor chip 120, the bonding pads 122 of the semiconductor chip 120 may be electrically connected with the signal pads 112 of the package substrate 110 via conductive bumps (not shown).

The molding member 130 may be formed on the upper surface of the package substrate 110 to cover the semiconductor chip 120 and the conductive wires 125. The molding member 130 may protect the semiconductor chip 120 and the conductive wires 125 from external environment. In some exemplary embodiments, the molding member 130 may include an epoxy molding compound (EMC).

The grounding member 140 may include a ground layer 142 and a ground contact 144. The ground layer 142 may be formed on an entire surface of the molding member 130 and side surfaces of the package substrate 110. The ground contact 144 may extend from a lower end of the ground layer 142 on the lower surface of the package substrate 110. The ground contact 144 may electrically make contact with the ground pads 114 of the package substrate 110. In some exemplary embodiments, the ground contact 144 and the ground pad 114 may be electrically connected with each other via the circuit pattern 116 of the package substrate 110. The grounding member 140 may include a metal.

In some exemplary embodiments, the grounding member 140 may have a thickness such that the total thickness of the package substrate 110 and the molding member 130 is substantially similar to the total thickness of the package substrate 110 and the molding member 130 with the grounding member 140 formed thereon. In other words, since the grounding member 140 is formed on the semiconductor package 100 itself, the grounding member 140 does not substantially increase the thickness of the semiconductor package 100. By contrast, a metal shield as provided in the related art adds a substantial thickness to the entire semiconductor package due to the space that must be provided between the metal shield and the semiconductor package.

The external terminals 150 may be mounted on the lower surface of the circuit pattern 116 exposed through the lower surface of the package substrate 110. The external terminals 150 may be electrically connected with the signal pads 112 of the package substrate 110 via the circuit pattern 116. In contrast, the external terminals 150 may not be connected with the ground contact 144 of the grounding member 140. In some exemplary embodiments, the external terminals 150 may include solder balls.

FIGS. 2 to 5 are cross-sectional views illustrating a method of manufacturing the semiconductor package in FIG. 1.

Referring to FIG. 2, the semiconductor chip 120 may be attached to the upper surface of the package substrate 110 using the adhesive.

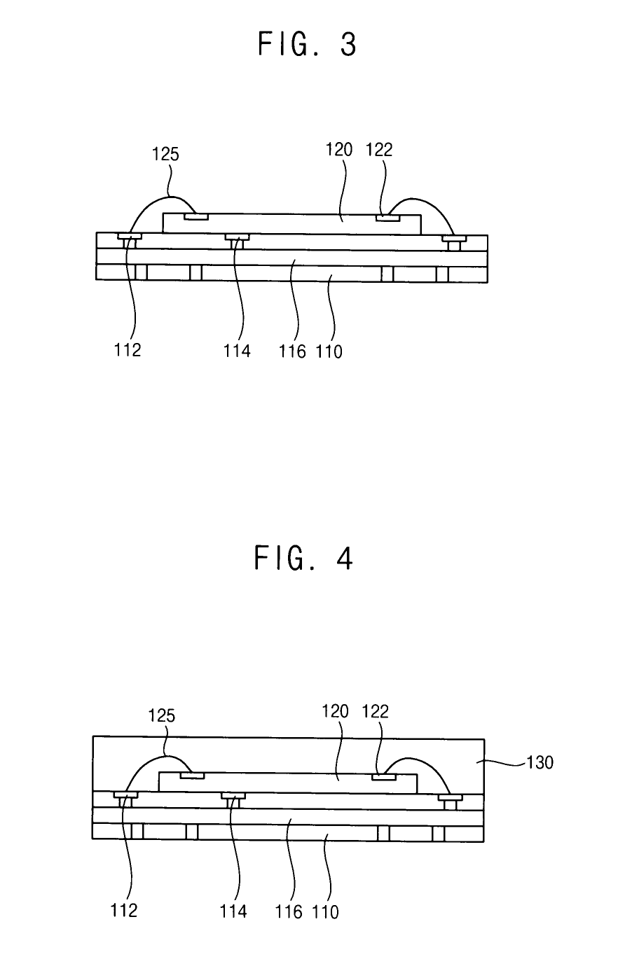

Referring to FIG. 3, the bonding pads 122 of the semiconductor chip 120 may be electrically connected with the signal pads 112 of the package substrate 110 using the conductive wires 125.

Referring to FIG. 4, the molding member 130 may be formed on the upper surface of the package substrate 110 to cover the semiconductor chip 120 and the conductive wires 125.

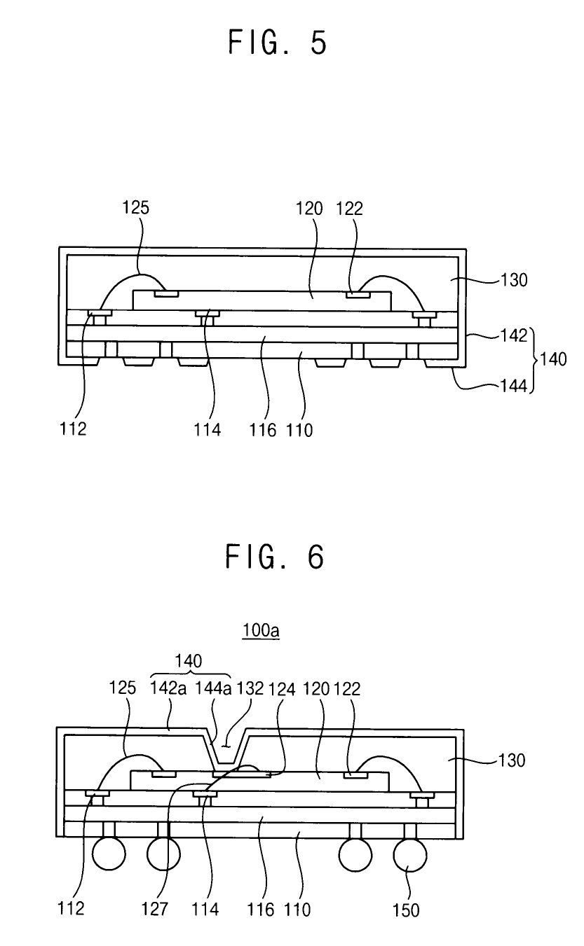

Referring to FIG. 5, the grounding member 140 may be formed on the entire surface of the molding member 130 and the lower surface of the package substrate 110. The ground contact 144 of the grounding member 140 may electrically make contact with the ground pad 114 of the package substrate 110. In some exemplary embodiments, the grounding member 140 may be formed by a plating process, a deposition process, etc.

The external terminals 150 may be mounted on the lower surface of the package substrate 110 to complete the semiconductor package 100 in FIG. 1.

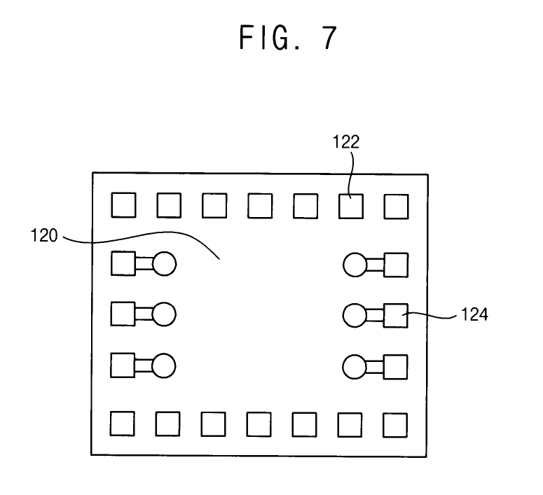

FIG. 6 is a cross-sectional view illustrating a semiconductor package in accordance with another exemplary embodiment, and FIG. 7 is a plan view illustrating a semiconductor chip of the semiconductor package in FIG. 6.

Referring to FIGS. 6 and 7, a semiconductor package 100a of this exemplary embodiment may include a package substrate 110, a semiconductor chip 120, first conductive wires 125, second conductive wires 127, a molding member 130, a grounding member 140a and external terminals 150.

In some exemplary embodiments, the package substrate 110, the first conductive wires 125 and the external terminals 150 may be substantially the same as the package substrate 110, the conductive wires 125 and the external terminals 150 in FIG. 1, respectively. Thus, further illustrations with respect to the package substrate 110, the first conductive wires 125 and the external terminals 150 are omitted herein for brevity.

The semiconductor chip 120 may be arranged on the upper surface of the package substrate 110. The semiconductor chip 120 may be attached to the upper surface of the package substrate 110 using an adhesive. In some exemplary embodiments, the semiconductor chip 120 may have bonding pads 122 and a ground pattern 124. The bonding pads 122 may be arranged on the upper surface of the semiconductor chip 120 in a first direction. The ground pattern 124 may be arranged on the upper surface of the semiconductor chip 120 in a second direction substantially perpendicular to the first direction. The bonding pads 122 may be electrically connected with an inner circuit (not shown) of the semiconductor chip 120. In contrast, the ground pattern 124 may be provided so as not to be electrically connected with the inner circuit of the semiconductor chip 120.

The second conductive wires 127 may be electrically connected with the ground pattern 124 of the semiconductor chip 120 and the ground pad 114 of the package substrate 110. In some exemplary embodiments, the second conductive wires 127 may include a metal wire such as an aluminum wire, a gold wire, etc.

The molding member 130 may be formed on the upper surface of the semiconductor chip 120 to cover the semiconductor chip 120, the first conductive wires 125 and the second conductive wires 127. The molding member 130 may protect the semiconductor chip 120, the first conductive wires 125 and the second conductive wires 127 from external environments. The molding member 130 may include an EMC.

In some exemplary embodiments, the molding member 130 may have an opening 132 configured to expose the ground pattern 124 of the semiconductor chip 120. The opening 132 may be formed at the upper surface of the molding member 130.

The grounding member 140a may include a ground layer 142a and a ground contact 144a. The ground layer 142a may be formed on the entire surface of the molding member 130 and the side surfaces of the package substrate 110 except for the opening 132. The ground contact 144a may extend from the ground layer 142a. The ground contact 144a may be formed on an inner surface of the opening 132. Thus, the ground contact 144a may be electrically connected with the ground pad 114 of the package substrate 110 via the second conductive wires 127.

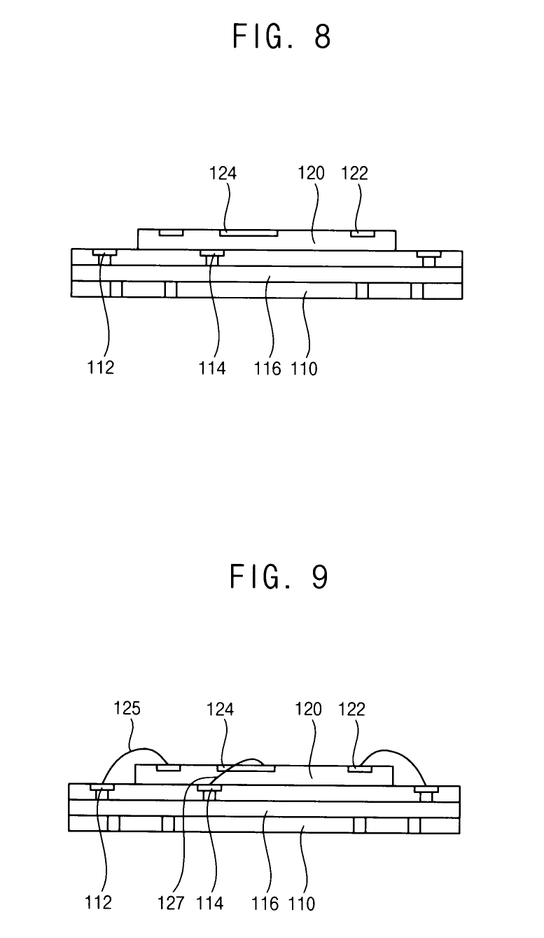

FIGS. 8 to 12 are cross-sectional views illustrating a method of manufacturing the semiconductor package in FIG. 6.

Referring to FIG. 8 the semiconductor chip 120 may be attached to the upper surface of the package substrate 110 using the adhesive.

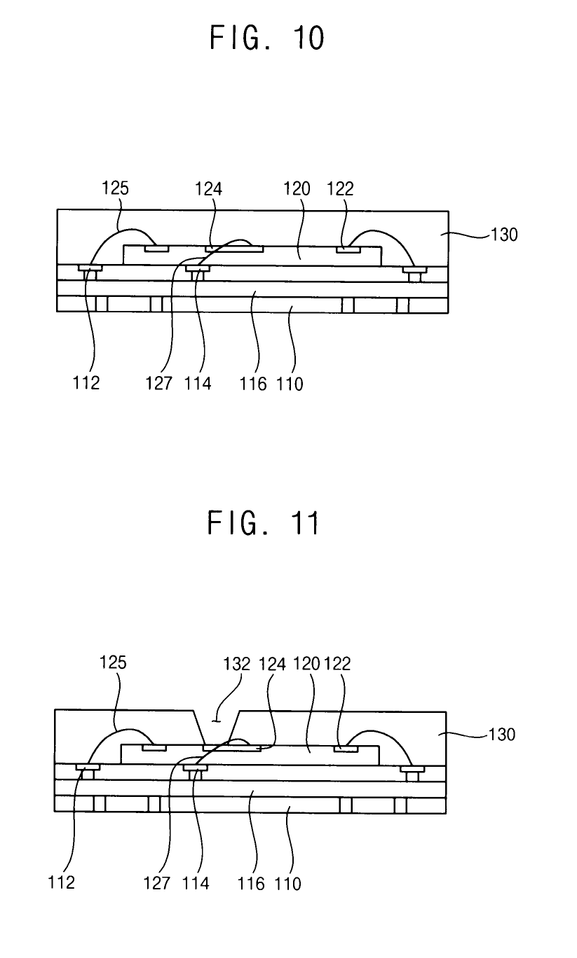

Referring to FIG. 9, the bonding pads 122 of the semiconductor chip 120 may be electrically connected with the signal pads 112 of the package substrate 110 using the first conductive wires 125. Further, the ground pattern 124 of the semiconductor chip 120 may be electrically connected with the ground pad 114 of the package substrate 110 using the second conductive wires 127.

Referring to FIG. 10, the molding member 130 may be formed on the upper surface of the package substrate 110 to cover the semiconductor chip 120, the first conductive wires 125 and the second conductive wires 127.

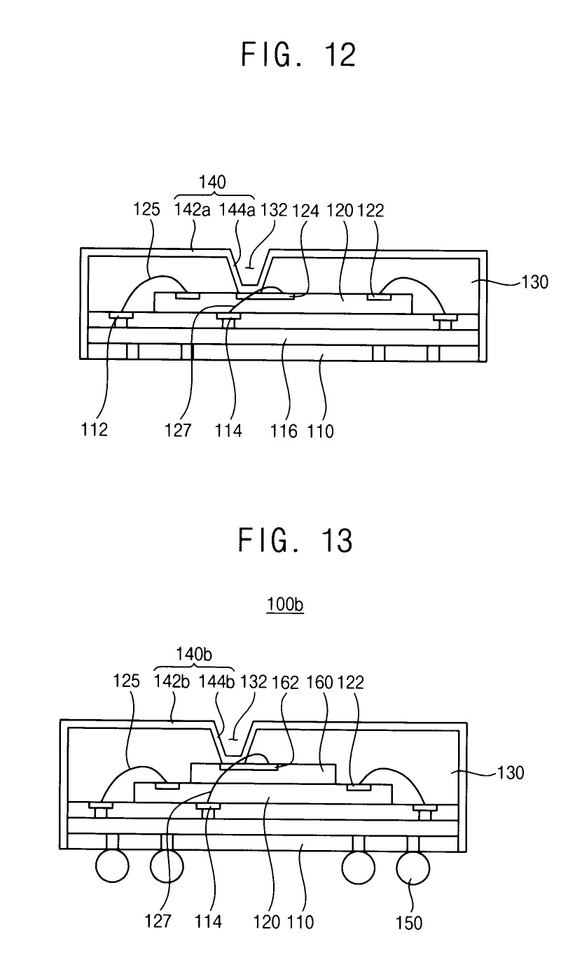

Referring to FIG. 11, the opening 132 may be formed through the molding member 130. The ground pattern 124 of the semiconductor chip 120 may be exposed through the opening 132.

Referring to FIG. 12, the grounding member 140a may be formed on the entire surface of the molding member 130, the side surfaces of the package substrate 110 and the inner surface of the opening 132. Thus, the ground contact 144a of the grounding member 140a may electrically make contact with the ground pad 114 of the package substrate 110 via the second conductive wires 127.

The external terminals 150 may be mounted on the lower surface of the package substrate 110 to complete the semiconductor package 100a in FIG. 6.

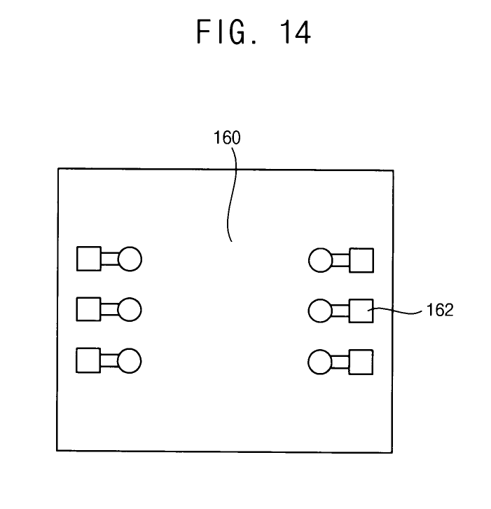

FIG. 13 is a cross-sectional view illustrating a semiconductor package in accordance with another exemplary embodiment, and FIG. 14 is a plan view illustrating an interposer chip of the semiconductor package in FIG. 13.

Referring to FIGS. 13 and 14, a semiconductor package 100b of this exemplary embodiment may include a package substrate 110, a semiconductor chip 120, an interposer chip 160, first conductive wires 125, second conductive wires 127, a molding member 130, a grounding member 140b and external terminals 150.

In some exemplary embodiments, the package substrate 110, the semiconductor chip 120, the first conductive wires 125 and the external terminals 150 may be substantially the same as the package substrate 110, the semiconductor chip 120, the conductive wires 125 and the external terminals 150 in FIG. 1, respectively. Thus, further illustrations with respect to the package substrate 110, the semiconductor chip 120, the first conductive wires 125 and the external terminals 150 are omitted herein for brevity.

The interposer chip 160 may be arranged on the upper surface of the semiconductor chip 120. In some exemplary embodiments, the interposer chip 160 may have a ground pattern 162. The ground pattern 162 may be arranged on the upper surface of the interposer chip 160.

The second conductive wires 127 may be electrically connected with the ground pattern 162 of the interposer chip 160 and the ground pad 114 of the package substrate 110. In some exemplary embodiments, the second conductive wires 127 may include a metal wire such as an aluminum wire, a gold wire, etc.

The molding member 130 may be formed on the upper surface of the semiconductor chip 120 to cover the semiconductor chip 120, the interposer chip 160, the first conductive wires 125 and the second conductive wires 127. The molding member 130 may protect the semiconductor chip 120, the interposer chip 160, the first conductive wires 125 and the second conductive wires 127 from external environments. The molding member 130 may include an EMC.

In some exemplary embodiments, the molding member 130 may have an opening 132 configured to expose the ground pattern 162 of the interposer chip 160. The opening 132 may be formed at the upper surface of the molding member 130.

The grounding member 140b may include a ground layer 142b and a ground contact 144b. The ground layer 142b may be formed on the entire surface of the molding member 130 and the side surfaces of the package substrate 110 except for the opening 132. The ground contact 144b may extend from the ground layer 142b. The ground contact 144b may be formed on an inner surface of the opening 132. Thus, the ground contact 144b may be electrically connected with the ground pad 114 of the package substrate 110 via the second conductive wires 127.

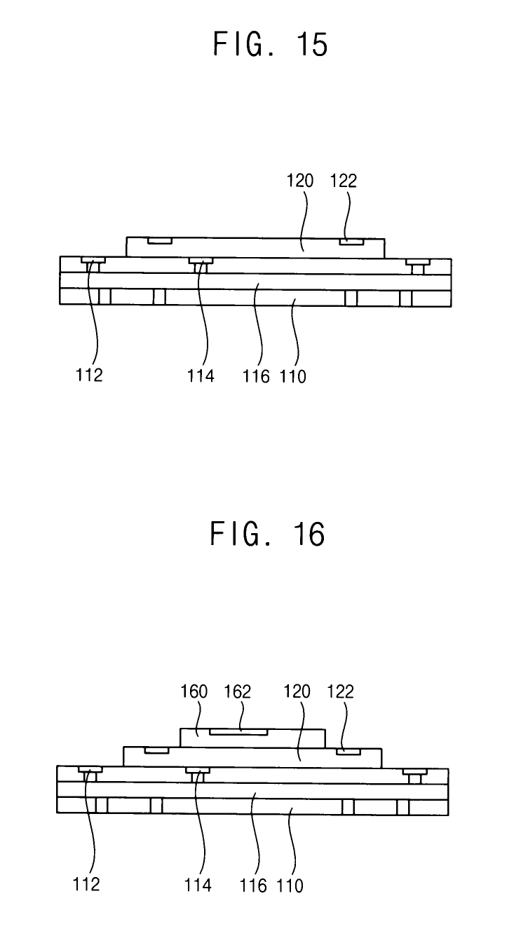

FIGS. 15 to 20 are cross-sectional views illustrating a method of manufacturing the semiconductor package in FIG. 13.

Referring to FIG. 15, the semiconductor chip 120 may be attached to the upper surface of the package substrate 110 using the adhesive.

Referring to FIG. 16, the interposer chip 160 may be arranged on the upper surface of the semiconductor chip 120. In some exemplary embodiments, the ground pattern 162 may be arranged on the upper surface of the interposer chip 160.

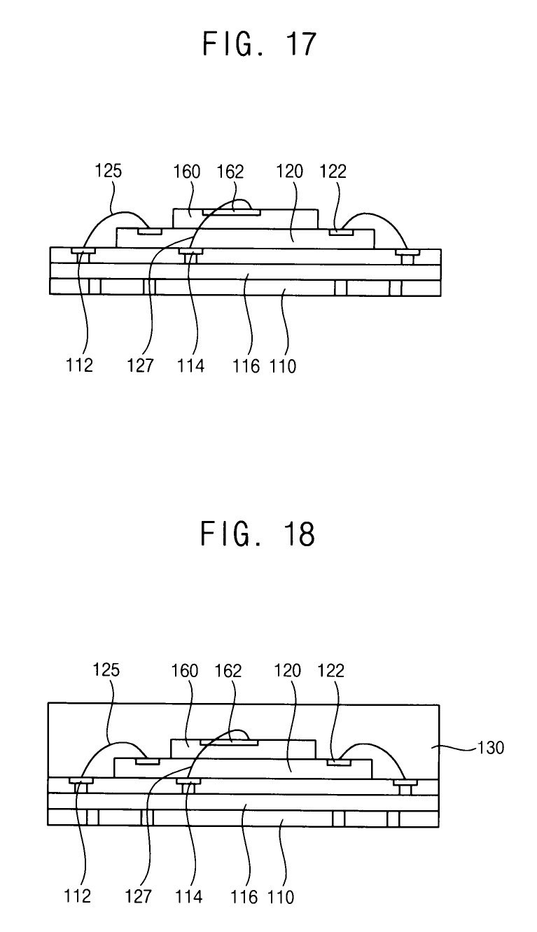

Referring to FIG. 17, the bonding pads 122 of the semiconductor chip 120 may be electrically connected with the signal pads 112 of the package substrate 110 using the first conductive wires 125. Further, the ground pattern 162 of the interposer chip 160 may be electrically connected with the ground pad 114 of the package substrate 110 using the second conductive wires 127.

Referring to FIG. 18, the molding member 130 may be formed on the upper surface of the package substrate 110 to cover the semiconductor chip 120, the interposer chip 160, the first conductive wires 125 and the second conductive wires 127.

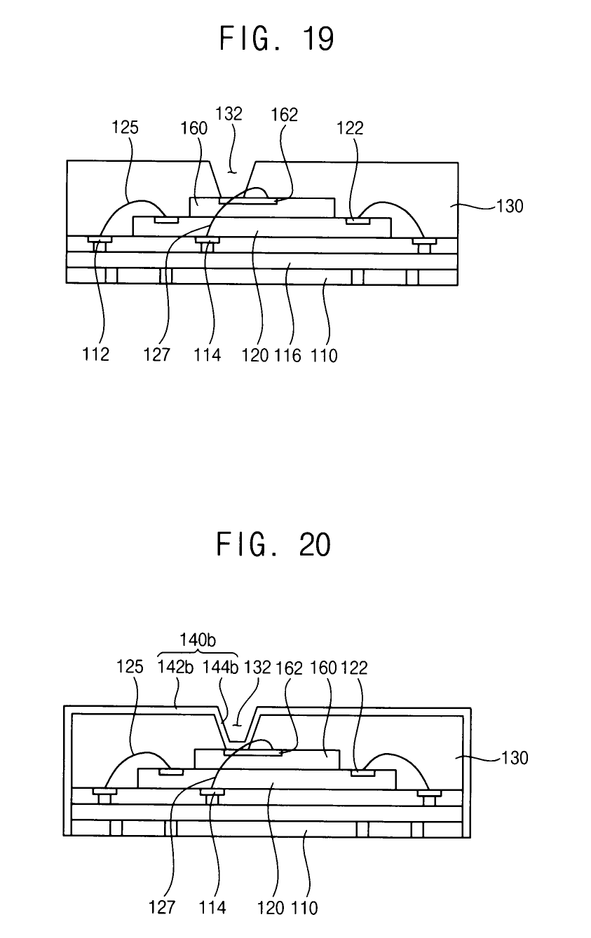

Referring to FIG. 19, the opening 132 may be formed through the molding member 130. The ground pattern 162 of the interposer chip 160 may be exposed through the opening 132.

Referring to FIG. 20, the grounding member 140b may be formed on the entire surface of the molding member 130, the side surfaces of the package substrate 110 and the inner surface of the opening 132. Thus, the ground contact 144b of the grounding member 140b may electrically make contact with the ground pad 114 of the package substrate 110 via the second conductive wires 127.

The external terminals 150 may be mounted on the lower surface of the package substrate 110 to complete the semiconductor package 100b in FIG. 13.

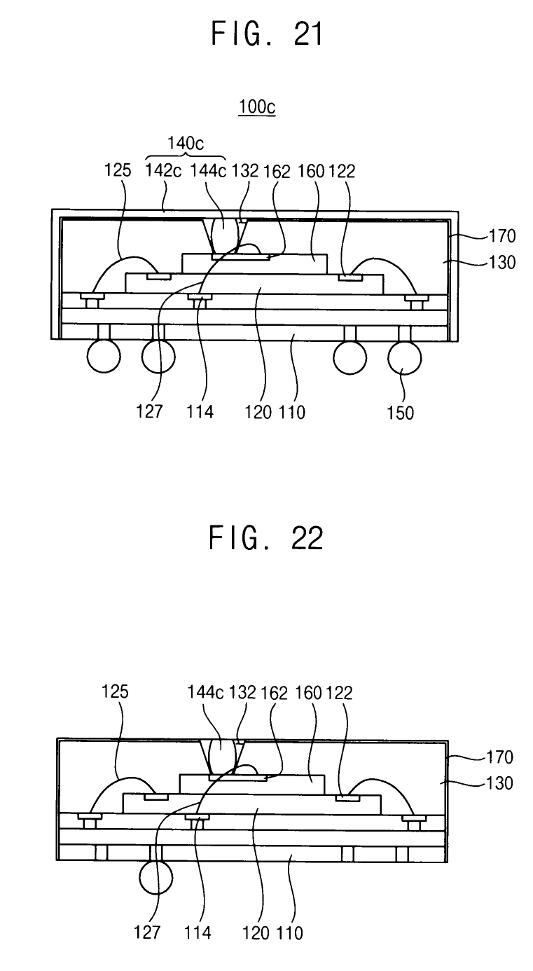

FIG. 21 is a cross-sectional view illustrating a semiconductor package in accordance with another exemplary embodiment.

In some exemplary embodiments, the semiconductor package 100c of this exemplary embodiment may include elements substantially the same as those of the semiconductor package 100b in FIG. 13 except for a grounding member 140c. Thus, the same reference numerals may refer to the same elements and further illustrations with respect to elements that are the same are omitted herein for brevity.

Referring to FIG. 21, the grounding contact 140c may include a ground can 142c and a ground contact 144c. The ground can 142c may be attached to the entire surface of the molding member 130, an upper surface of the ground contact 144c and the side surfaces of the package substrate 110 using an adhesive layer 170. The ground contact 144c may be formed in the opening 132 of the molding member 130. In some exemplary embodiments, the ground contact 144c may include a solder ball.

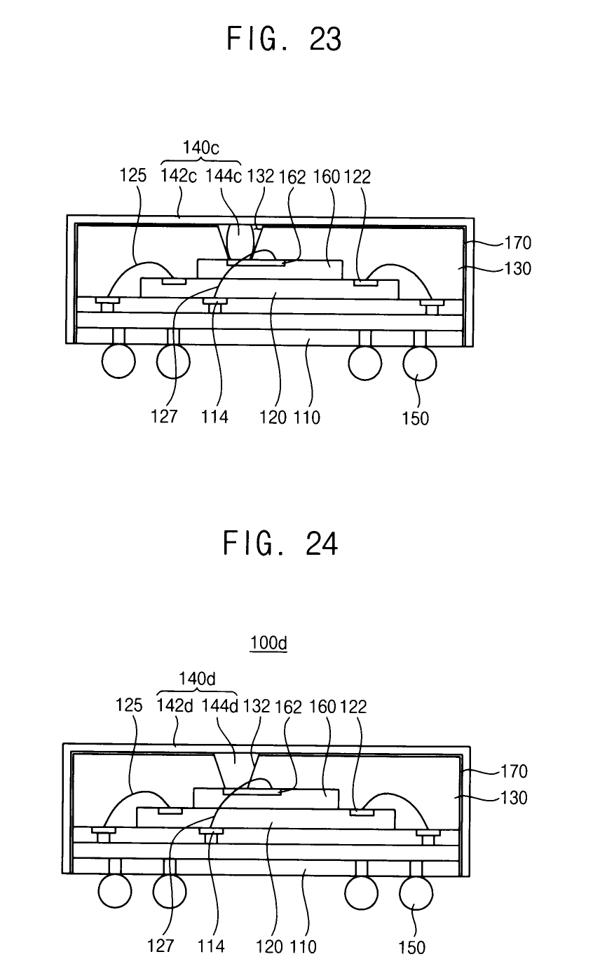

FIGS. 22 and 23 are cross-sectional views illustrating a method of manufacturing the semiconductor package in FIG. 21.

Processes substantially the same as those illustrated with reference to FIGS. 15 to 19 may be performed to form the opening 132 in the molding member 130. The ground pattern 162 may be exposed through the opening 132.

Referring to FIG. 22, the ground contact 144c may be formed in the opening 132. In some exemplary embodiments, the solder ball (not shown) may be placed in the opening 132. A reflow process may be performed on the solder ball to form the ground contact 144c in the opening 132. The adhesive layer 170 may be formed on the entire surface of the molding member 130.

Referring to FIG. 23, the ground can 142c may be attached to the entire surface of the molding member 130, the upper surface of the ground contact 144c and the side surfaces of the package substrate 110 using the adhesive layer 170. Thus, the ground contact 144c of the grounding member 140c may be electrically connected with the ground pad 114 of the package substrate 110 via the second conductive wires 127.

The external terminals 150 may be mounted on the lower surface of the package substrate 110 to complete the semiconductor package 100b in FIG. 21.

FIG. 24 is a cross-sectional view illustrating a semiconductor package in accordance with another exemplary embodiment.

In some exemplary embodiments, the semiconductor package 100d of this exemplary embodiment may include elements substantially the same as those of the semiconductor package 100b in FIG. 13 except for a grounding member 140d. Thus, the same reference numerals may refer to the same elements and further illustrations with respect to elements that are the same may be omitted herein for brevity.

Referring to FIG. 24, the grounding contact 140d may include a ground can 142d and a ground contact 144d. The ground contact 144d may be configured to fully fill the opening 132 of the molding member 130. In some exemplary embodiments, the ground contact 144d may be formed by filling the opening 132 with a metal. The ground can 142d may be attached to the entire surface of the molding member 130, the upper surface of the ground contact 144d and the side surfaces of the package substrate 110.

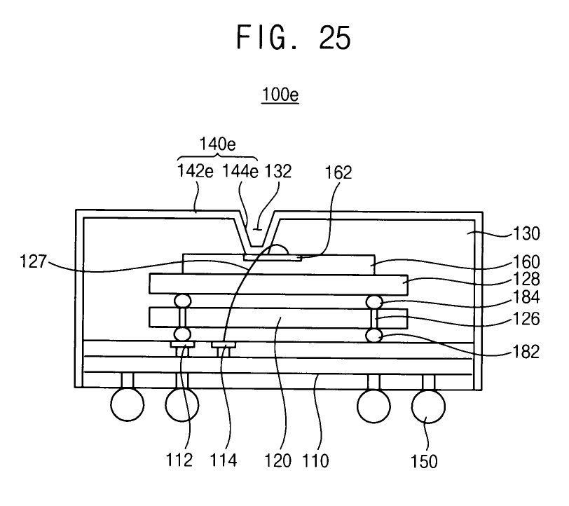

FIG. 25 is a cross-sectional view illustrating a semiconductor package in accordance with another exemplary embodiment.

In some exemplary embodiments, the semiconductor package 100e of this exemplary embodiment may include elements substantially the same as those of the semiconductor package 100b in FIG. 13 except for further including a second semiconductor chip 128. Thus, the same reference numerals may refer to the same elements and further illustrations with respect to elements that are the same may be omitted herein for brevity.

Referring to FIG. 25, the first semiconductor chip 120 may have plugs 126. The plug 126 may be vertically formed through the first semiconductor chip 120. Some of ordinary skill in the art will understand that only one plug may be provided or a plurality of plugs may be provided.

First conductive bumps 182 may be interposed between the first semiconductor chip 120 and the package substrate 110. The first conductive bumps 182 may be electrically connected between the plug 126 of the first semiconductor chip 120 and the signal pad 112 of the package substrate 110.

The second semiconductor chip 128 may be stacked on the upper surface of the first semiconductor chip 120. Second conductive bumps 184 may be interposed between the first semiconductor chip 120 and the second semiconductor chip 128. The second conductive bumps 184 may make contact with the plug 126 to electrically connect the first semiconductor chip 120 with the second semiconductor chip 128.

The interposer chip 160 may be stacked on the upper surface of the second semiconductor chip 128. The ground pattern 162 of the interposer chip 160 may be electrically connected with the ground pad 114 of the package substrate 110 via the second conductive wires 127.

Alternatively, a ground pattern (not shown) may be arranged on the upper surface of the second semiconductor chip 128 without the interposer chip 160.

In some exemplary embodiments, the grounding member 140e may have a structure substantially the same as that of the grounding member 140b in FIG. 13. Thus, further illustrations with respect to the grounding member 140e are omitted herein for brevity.

According to some exemplary embodiments, the grounding member may be formed on the surface of the molding member. Thus, the grounding member does not increase a thickness of the semiconductor package. As a result, the semiconductor package may have an EMI-resistant structure and a thin thickness.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of the present inventive concept. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

What is claimed is:

1. A semiconductor package comprising:
a package substrate having a ground pad and a signal pad;
a semiconductor chip arranged on an upper surface of the package substrate, the semiconductor chip electrically connected to the signal pad of the package substrate;
a molding member formed on the upper surface of the package substrate to cover the semiconductor chip; and
a grounding member arranged on a surface of the molding member, the grounding member electrically connected to the ground pad.

2. The semiconductor package of claim 1, wherein the grounding member comprises:
a ground layer formed on the surface of the molding member; and
a ground contact extending from the ground layer over a portion of a lower surface of the package substrate, the ground contact electrically connected to the ground pad.

3. The semiconductor package of claim 1, wherein the semiconductor chip has a ground pattern electrically connected to the ground pad, and the molding member has an opening configured to expose the ground pattern of the semiconductor chip,
wherein the grounding member comprises:
a ground layer formed on the surface of the molding member; and
a ground contact formed in the opening, the ground contact electrically connected to the ground pattern of the semiconductor chip.

4. The semiconductor package of claim 1, further comprising an interposer chip stacked on an upper surface of the semiconductor chip, the interposer chip having a ground pattern electrically connected between the ground pad and the grounding member.

5. The semiconductor package of claim 4, wherein the molding member has an opening configured to expose the ground pattern of the interposer chip,
wherein the grounding member comprises:
a ground layer formed on the surface of the molding member; and
a ground contact formed in the opening, the ground contact electrically connected to the ground pattern of the interposer chip.

6. The semiconductor package of claim 1, further comprising a second semiconductor chip stacked on an upper surface of the semiconductor chip and covered with the molding member.

7. The semiconductor package of claim 6, further comprising a plug formed through the semiconductor chip to electrically connect the second semiconductor chip with the signal pad.

8. The semiconductor package of claim 4, wherein the grounding member comprises:
a ground contact formed on the surface of the molding member; and
a ground can attached to the surface of the molding member, the ground contact electrically connected to the ground can and the ground pad.

9. A method of manufacturing a semiconductor package, the method comprising:
arranging a semiconductor chip on an upper surface of a package substrate that has a ground pad and a signal pad, the semiconductor chip electrically connected to the signal pad of the package substrate;
forming a molding member on the upper surface of the package substrate to cover the semiconductor chip; and
forming a grounding member on a surface of the molding member, the grounding member electrically connected to the ground pad.

10. The method of claim 9, wherein forming the grounding member comprises:
forming a ground layer on the surface of the molding member; and
extending a ground contact from the ground layer over a portion of a lower surface of the package substrate, the ground contact electrically connected to the ground pad.

11. The method of claim 9, further comprising forming a ground pattern on the semiconductor chip, the ground pattern electrically connected to the ground pad,
wherein forming the grounding member comprises:
forming a ground layer on the surface of the molding member; and
extending a ground contact from the ground layer, the ground contact electrically connected to the ground pattern of the semiconductor chip.

12. The method of claim 11, wherein forming the molding member comprises forming an opening in the molding member, the opening configured to expose the ground pattern of the semiconductor chip,
wherein the ground contact is formed in the opening.

13. The method of claim 9, further comprising stacking an interposer chip on an upper surface of the semiconductor chip, the interposer chip having a ground pattern electrically connected between the ground pad and the grounding member.

14. The method of claim 13, wherein forming the grounding member comprises:
forming a ground layer on the surface of the molding member; and
extending a ground contact from the ground layer, the ground contact electrically connected to the ground pattern of the interposer chip.

15. The method of claim 14, wherein forming the molding member comprises forming an opening in the molding member, the opening configured to expose the ground pattern of the interposer chip,
wherein the ground contact is formed in the opening.

16. A semiconductor package comprising:
a package substrate having a semiconductor chip arranged on an upper surface thereof, and a ground pad;
a molding member formed on the upper surface of the package substrate to cover the semiconductor chip; and
a grounding member formed directly on a surface of the molding member and electrically connected to the ground pad to electrically shield the semiconductor chip from electromagnetic interference.

17. The semiconductor package of claim 16, wherein the grounding member is formed over an entire upper surface of the molding member, and over the side surface of the molding member and the package substrate.

18. The semiconductor package of claim 17, wherein the grounding member further extends over a portion of a lower surface of the package substrate to connect to the ground pad.

19. The semiconductor package of claim 17, wherein the semiconductor chip comprises a ground pad formed on an upper surface of the semiconductor chip, the molding member has an opening formed therein to expose the ground pad, and the grounding member extends through the opening to electrically contact the ground pad.

20. The semiconductor package of claim 17, wherein the semiconductor chip comprises a ground pad formed on an upper surface of the semiconductor chip, the molding member has an opening formed therein to expose the ground pad, and wherein the grounding member is a ground can electrically connected to the ground pad through the opening.
